(19) United States
(12) Patent Application Publication
(10) Pub. No.: US 2026/0237973 A1
(43) Pub. Date: Aug. 13, 2026

(54) SEMICONDUCTOR LASER DEVICE AND METHOD FOR PRODUCING A SEMICONDUCTOR LASER DEVICE

(71) Applicant: ams-OSRAM International GmbH, Regensburg (DE)

(72) Inventors: Nicole BERNER, Walderbach (DE); Jan MARFELD, Regensburg (DE); Erik HEINEMANN, Regensburg (DE); Anna BUTSCH, Regensburg (DE); Jörg Erich SORG, Regensburg (DE)

(73) Assignee: ams-OSRAM International GmbH, Regensburg (DE)

(21) Appl. No.: 19/471,766

(22) PCT Filed: Mar. 21, 2024
(86) PCT No.: PCT/EP2024/057646

§ 371 Date: Oct. 2, 2025

(30) Foreign Application Priority Data
Apr. 5, 2023 (DE) 10 2023 108 783.5

(51) Int. Cl. H01S 5/40; H01S 5/02326

(52) U.S. Cl. CPC H01S 5/4012; H01S 5/02326; H01S 5/4031; H01S 5/4093

(57) ABSTRACT

The invention relates to a semiconductor laser device including a first semiconductor laser, which is designed to emit a first radiation with a first wavelength of maximum intensity along a first main emission direction during operation of the semiconductor laser device, a second semiconductor laser, which is designed to emit a second radiation with a second wavelength of maximum intensity, greater than the first wavelength of maximum intensity, along a second main emission direction during operation of the semiconductor laser device, a prismatic element having a base, a radiation entry face and a radiation exit face wherein the radiation entry face and the radiation exit face are opposite side faces of the prismatic element running obliquely to each other, wherein the first radiation and the second radiation impinge on the radiation entry face of the prismatic element, and wherein the first main emission direction and the second main emission direction are arranged relative to a normal of the radiation entry face such that the semiconductor laser device emits the first radiation and the second radiation superimposed at the radiation exit face. The invention also relates to a method for producing a semiconductor laser device.

### CROSS-REFERENCE TO RELATED APPLICATIONS

The present application is a national stage entry from International Application No. PCT/EP2024/057646, filed on Mar. 21, 2024, published as International Publication No. WO 2024/208602 A1 on Oct. 10, 2024, and claims priority to German Patent Application No. 10 2023 108 783.5, filed Apr. 5, 2023, the disclosures of all of which are hereby incorporated by reference in their entireties.

### FIELD

The present application relates to a semiconductor laser device and a method of manufacturing a semiconductor laser device.

### BACKGROUND

For different laser applications, the radiation from different semiconductor lasers, in particular with different emission wavelengths, is to be superimposed. This can be achieved, for example, by using lens systems or beam combiners. In practice, however, this is complex and costly.

One task is to specify a semiconductor laser device with which efficient superposition of laser beams can be achieved. Furthermore, a method is to be specified with which such a semiconductor laser device can be manufactured reliably and inexpensively.

These tasks are solved, inter alia, by a semiconductor laser device or a method with the features of the independent patent claims, respectively. Further configurations and practical features are the subject of the dependent patent claims.

### SUMMARY

A semiconductor laser device with at least one first semiconductor laser and a second semiconductor laser is specified. The semiconductor laser device may also have one or more additional semiconductor lasers. The semiconductor laser device is configured, for example, as a surface-mounted device (smd). However, the concept described is not limited to specific designs.

The first semiconductor laser and/or the second semiconductor laser is, for example, a semiconductor laser with an emission region or with several emission regions, wherein, in the case of several emission regions, at least some or all of the emission regions can be electrically contacted independently of one another, for example. For example, the first semiconductor laser and/or the second semiconductor laser is an edge-emitting semiconductor laser. An emission region is, for example, a ridge-shaped region (also referred to as a ridge). The emission regions of a semiconductor laser, for example of the first semiconductor laser and/or the second semiconductor laser and/or, if applicable, a further semiconductor laser, can emit radiation with the same wavelength of maximum intensity. Alternatively, the emission regions of a semiconductor laser may differ from one another in terms of their wavelength of maximum intensity, for example by at most 10 nm or by at most 5 nm. In other words, the ridge-shaped regions of a semiconductor laser chip may have emission regions that do not differ from one another in terms of their maximum intensity wavelength, or only differ slightly, for example by at most 10 nm or by at most 5 nm.

For example, at least one of the semiconductor lasers is configured to generate radiation in the red, green or blue spectral range. Two or more semiconductor lasers can also emit in the same spectral range, for example, in the green spectral range. Alternatively or in addition, at least one of the semiconductor lasers can also be configured to generate radiation in the ultraviolet or infrared spectral range.

According to at least one embodiment of the semiconductor laser device, the first semiconductor laser is configured to emit a first radiation with a first wavelength of maximum intensity along a first main emission direction during operation of the semiconductor laser device. The first main emission direction is considered to be the direction along which the first radiation propagates after exiting the first semiconductor laser, for example in a free beam region adjacent to the first semiconductor laser. In the event that the first semiconductor laser has several emission regions with different wavelengths of maximum intensity, the first wavelength of maximum intensity is considered to be the wavelength resulting from an averaging of the individual wavelengths in the respective local maxima of the emission regions.

According to at least one embodiment of the semiconductor laser device, the second semiconductor laser is configured to emit a second radiation with a second wavelength of maximum intensity along a second main emission direction during operation of the semiconductor laser device. The second main emission direction is considered to be the direction along which the second radiation propagates after exiting the second semiconductor laser. In the event that the second semiconductor laser has several emission regions with different maximum intensity wavelengths, the second maximum intensity wavelength is considered to be the wavelength resulting from averaging the individual wavelengths in the respective local maxima of the emission regions.

According to at least one embodiment of the semiconductor laser device, the semiconductor laser device comprises a prismatic element. The prismatic element comprises, for example, a base area, a radiation entry surface, and a radiation exit surface. The side surfaces of the prismatic element extend, for example, each perpendicular or oblique to the base area. The radiation entry surface and the radiation exit surface are, for example, side surfaces of the prismatic element that are oblique to each other and opposite each other. An angle between the radiation entry surface and the radiation exit surface is, for example, between 10° and 80° inclusive. For example, the base area has a triangular shape, but one or more corners of the triangle may also be cut off or rounded. At least in a region in which radiation impinges on the radiation entry surface during operation of the semiconductor laser device, the radiation entry surface is flat. Upon radiation entry, therefore, only a deflection occurs at the radiation entry surface due to refraction, but no additional widening or bundling due to the shape of the radiation entry surface itself.

The radiation exit surface is flat at least in an area in which radiation exits from the prismatic element during operation of the semiconductor laser device.

In particular, when the radiation passes through the prismatic element, both the first radiation and the second radiation undergo exactly one refraction at the radiation entry surface and exactly one refraction at the radiation exit surface. Furthermore, no further beam deflection occurs, in particular between the radiation entry through the radiation entry surface and the radiation exit through the radiation exit surface. In other words, the radiation travels within the prismatic element directly from the radiation entry surface to the radiation exit surface.

According to at least one embodiment of the semiconductor laser device, the first radiation and the second radiation impinge on the radiation entry surface of the prismatic element, wherein the first main emission direction and the second main emission direction are arranged relative to a normal of the radiation entry surface such that the semiconductor laser device emits the first radiation and the second radiation superimposed at the radiation exit surface.

For example, a first main radiation direction of the first radiation and a second main radiation direction of the second radiation after exiting the semiconductor laser device differ from each other by at most 10°, or by at most 5°, or by at most 3°, or by at most 1°.

The superposition of the first radiation and the second radiation is achieved in particular by the first radiation and the second radiation impinging on the radiation entry surface at angles relative to the normal of the radiation entry surface that are different from one another. The required angles result from the law of refraction for a refraction at the radiation entry surface and at the radiation exit surface, depending on the first wavelength of maximum intensity, the second wavelength of maximum intensity, a first refractive index of the prismatic element for the first wavelength of maximum intensity and a second refractive index of the prismatic element for the second wavelength of maximum intensity.

In at least one embodiment, the semiconductor laser device comprises a first semiconductor laser which is configured to emit, during operation of the semiconductor laser device, a first radiation with a first wavelength of maximum intensity along a first main emission direction, and a second semiconductor laser which is arranged to emit, during operation of the semiconductor laser device, a second radiation with a second wavelength of maximum intensity along a second main emission direction. The semiconductor laser device further comprises a prismatic element with a base area, a radiation entry surface, and a radiation exit surface, wherein the radiation entry surface and the radiation exit surface are side surfaces of the prismatic element which are oblique to each other and opposite to each other. The first radiation and the second radiation impinge on the radiation-entrance surface of the prismatic element, and the first main emission direction and the second main emission direction are arranged relative to a normal of the radiation-entrance surface such that the semiconductor laser device emits the first radiation and the second radiation superimposed at the radiation exit surface. In particular, at least one of the semiconductor lasers comprises a plurality of emission regions.

The semiconductor laser device makes use of the effect that, in a prismatic element, due to its dispersion, i.e., the dependence of the refractive index of the prismatic element on the wavelength of the impinging radiation, radiation components with different wavelengths are deflected to different degrees by the prismatic element and, consequently, the semiconductor lasers can be arranged in relation to each other in such a way that the prismatic element superimposes the first radiation and the second radiation. In other words, the present application pursues the approach of reversing the principle of the dispersion of, for example, white light by a prism. Ideally, the main radiation directions for the first radiation and for the second radiation are congruent immediately after exiting the radiation exit surface or at least at an angle of at most 5° or at most an 3° or at most 1°.

It has turned out that such radiation superposition can be achieved particularly easily and inexpensively for two or more semiconductor lasers, for example three semiconductor lasers, especially in comparison to superposition using lenses, a beam combiner or a photonic integrated circuit (PIC).

According to at least one embodiment of the semiconductor laser device, the prismatic element has a higher refractive index for the first wavelength of maximum intensity than for the second wavelength of maximum intensity, wherein the first main emission direction is arranged at a larger angle to the normal of the radiation entry surface than the second main emission direction. The prismatic element thus exhibits normal dispersion, in which the refractive index decreases with increasing wavelength. The radiation with the first wavelength is therefore refracted more strongly at the radiation entry surface and at the radiation exit surface than radiation with the second wavelength, so that a superposition of the radiation can be achieved at the radiation exit surface if the first radiation impinges at a greater angle to the radiation exit surface than the second radiation. In principle, a prismatic element can also be used which has a lower refractive index for the first wavelength of maximum intensity than for the second wavelength of maximum intensity. In this case, the first main direction of emission is arranged at a smaller angle to the normal of the radiation entry surface than the second main direction of emission.

According to at least one embodiment of the semiconductor laser device, a material of the prismatic element has an Abbe number of at most 50. The Abbe number is a dimensionless number used to characterize the optical dispersive properties of optical glasses. It is a measure of how much the refractive index changes with the wavelength of light. The greater the relative dispersion of the glass, the smaller its reciprocal value, the Abbe number. A glass with an Abbe number of at most 50 is also referred to as flint glass. With a comparatively large relative dispersion between the first wavelength and the second wavelength, there are also correspondingly larger angle differences between the first main emission direction and the second main emission direction relative to the normal of the radiation entry surface. This facilitates positioning of the first semiconductor laser and the second semiconductor laser relatively close to the prismatic element. The smaller the distance between the semiconductor lasers and the prismatic element, the smaller the beam expansion of the first radiation and the second radiation up to the prismatic element due to the divergence of the semiconductor lasers.

According to at least one embodiment of the semiconductor laser device, the material of the prismatic element has an Abbe number of at most 30. For example, the prismatic element contains a flint glass SF6 or SF10. In principle, however, other materials that are transparent to the first radiation and the second radiation can also be used, for example other mineral or organic glasses.

According to at least one embodiment of the semiconductor laser device, the first main emission direction and the second main emission direction extend parallel to the base area of the prismatic element. The first radiation and the second radiation therefore extend parallel to the base area of the prismatic element before entering the prismatic element and after exiting the prismatic element.

According to at least one embodiment of the semiconductor laser device, at least one of the semiconductor lasers comprises a plurality of emission regions, wherein the emission regions are arranged next to one another as viewed along a direction perpendicular to the base area of the prismatic element. In a top view of the base area of the prismatic element, the emission regions can therefore overlap completely or at least partially. In this case, in an edge-emitting semiconductor laser, a fast axis runs parallel to the base area of the prismatic element.

According to at least one embodiment of the semiconductor laser device, at least one of the semiconductor lasers comprises a plurality of emission regions, wherein the emission regions are arranged next to each other along a direction parallel to the base area of the prismatic element. In an edge-emitting semiconductor laser, a slow axis thus extends parallel to the base area of the prismatic element.

According to at least one embodiment of the semiconductor laser device, the semiconductor laser device has a mounting carrier with a mounting surface, wherein the first semiconductor laser, the second semiconductor laser, and the prismatic element are arranged on the mounting surface. The first semiconductor laser and the second semiconductor laser can each be attached to the mounting carrier directly or via one or more intermediate carriers.

According to at least one embodiment of the semiconductor laser device, the base area of the prismatic element extends parallel to the mounting surface of the mounting carrier. For example, the radiation entry surface and the radiation exit surface of the prismatic element extend perpendicular to the mounting plane.

According to at least one embodiment of the semiconductor laser device, the base area of the prismatic element extends perpendicular to the mounting surface. A side surface of the prismatic element thus faces the mounting surface and can Serve to secure the prismatic element to the mounting surface. The radiation entry surface and/or the radiation exit surface extend, for example, obliquely to the mounting surface.

According to at least one embodiment of the semiconductor laser device, the first radiation and the second radiation pass through free beam region after emerging from the first semiconductor laser and the second semiconductor laser, respectively, with the prismatic element immediately following the free beam region. The prismatic element is therefore the first element through which the first radiation and the second radiation pass after the free beam region.

However, the first semiconductor laser and/or the second semiconductor laser may comprise an optical element, for example for collimation along the axis of fast divergence, which is attached directly to the first semiconductor laser or the second semiconductor laser and is thus located upstream of the free beam region.

In an alternative configuration, an optical element is arranged between the first semiconductor laser and the prismatic element and/or between the second semiconductor laser and the prismatic element, for example for collimation along at least one direction, such as along the axis of fast divergence, or along two mutually perpendicular directions.

According to at least one embodiment of the semiconductor laser device, the semiconductor laser device comprises a third semiconductor laser which is configured to emit a third radiation with a third wavelength of maximum intensity along a third main emission direction during operation of the semiconductor laser device. For example, the wavelengths of maximum intensity differ from each other in pairs by at least 20 nm or at least 50 nm. For example, the three semiconductor lasers together generate radiation in the blue spectral range, in the green spectral range, and in the red spectral range, so that the semiconductor laser device emits superimposed mixed radiation which may appear white to the human eye. However, two or more, for example three, semiconductor lasers may also have their wavelength of maximum intensity in the same spectral range, for example in the green spectral range.

Furthermore, a method of manufacturing a semiconductor laser device is specified. The method is particularly suitable for a semiconductor laser device described above. Features described in connection with the semiconductor laser device may therefore also apply to the method or vice versa.

According to at least one embodiment of the method, the method comprises the steps of applying a prismatic element to a mounting carrier, applying a first semiconductor laser to the mounting carrier, and applying the second semiconductor laser to the mounting carrier.

The list of steps does not imply any order in which the steps are performed during manufacture.

According to at least one embodiment of the method, the step of applying the prismatic element is performed after applying at least one or both of the first semiconductor laser and the second semiconductor laser. In particular, the first semiconductor laser and the second semiconductor laser can be operated while an optimal angular position of the prismatic element is determined. In other words, the prismatic element can be rotated on the mounting carrier for fine adjustment so that the first radiation and the second radiation overlap as well as possible. For example, the first semiconductor laser and the second semiconductor laser can be placed at a defined position at a defined angle and fixed to the mounting surface, for example by soldering or sintering. Subsequently, active adjustment of the prism can take place, whereby optimization of the superposition can be achieved by rotating the prismatic element about its own axis, which runs in particular perpendicular to the base area.

According to at least one embodiment of the method, at least one of the first semiconductor laser and the second semiconductor laser is applied to the mounting carrier after the prismatic element has been applied to the mounting carrier. In this case, one or more semiconductor lasers can be rotated relative to the prismatic element, in particular in a plane parallel to the base area of the prismatic element, so that the first radiation and the second radiation are optimally superimposed by means of the prismatic element.

In the event that the semiconductor lasers are mounted after the prismatic element has been applied, mounting is preferably carried out using a method in which the already mounted prismatic element itself and a connecting layer between the prismatic element and the mounting carrier are not heated excessively. For example, bonding initiated by ultraviolet radiation is suitable.

A semiconductor laser device described here is generally suitable for applications in which the radiation from two or more semiconductor lasers, each with one or more emission regions, is to be superimposed. Comparatively high laser powers can also be achieved.

The semiconductor laser device can be configured for use in a vehicle, such as a motor vehicle, for example for a headlight. Furthermore, the semiconductor laser device can be configured to be particularly compact and can be used in particular as a compact laser light source in portable devices. For example, the semiconductor laser device is suitable for projection applications, head-up displays, augmented reality displays, virtual reality displays, augmented reality glasses, or virtual reality glasses.

Features described in connection with at least one embodiment of the semiconductor laser or the method can also be combined with other features described in connection with at least one embodiment of the semiconductor laser or the method, as long as these features are not mutually exclusive.

Further configurations and practical features are apparent from the following description of the exemplary embodiments in connection with the figures.

### BRIEF DESCRIPTION OF THE DRAWINGS

In the Figures:

FIGS. 1A to 1L show an exemplary embodiment of a semiconductor laser device in schematic plan view (FIG. 1A), schematic side view (FIG. 1B) and in perspective view (FIG. 1C), wherein FIG. 1D shows an example of a refractive index of the prismatic element as a function of wavelength, FIGS. 1E, 1G and 1I each show a beam path for the radiation of a semiconductor laser, FIGS. 1F, 1H and 1J each show a corresponding contour diagram of a beam profile of the radiation components after exit from the radiation exit surface, and FIGS. 1K and 1L show corresponding superpositions of the three radiation components by means of a beam path (FIG. 1K) and a contour diagram of a beam profile (FIG. 1L);

FIGS. 2A to 2C show an exemplary embodiment of a semiconductor laser device by way of a top view (FIG. 2A), a side view (FIG. 2B), and a perspective view (FIG. 2C);

FIGS. 3A to 3C show an exemplary embodiment of a semiconductor laser device by way of a top view (FIG. 3A), a side view (FIG. 3B), and a perspective view (FIG. 3C).

FIGS. 4A to 4C show an exemplary embodiment of a method for manufacturing a semiconductor laser device by way of intermediate steps shown in schematic top views; and

FIGS. 5A to 5C show an exemplary embodiment of a method of manufacturing a semiconductor laser device by way of intermediate steps shown in schematic top views.

### DETAILED DESCRIPTION

The figures are schematic representations and therefore not necessarily true to scale. In particular, comparatively small elements or layer thicknesses may be exaggerated for improved representation and/or better understanding.

Identical, similar, or equivalent elements are designated by the same reference numerals in the figures.

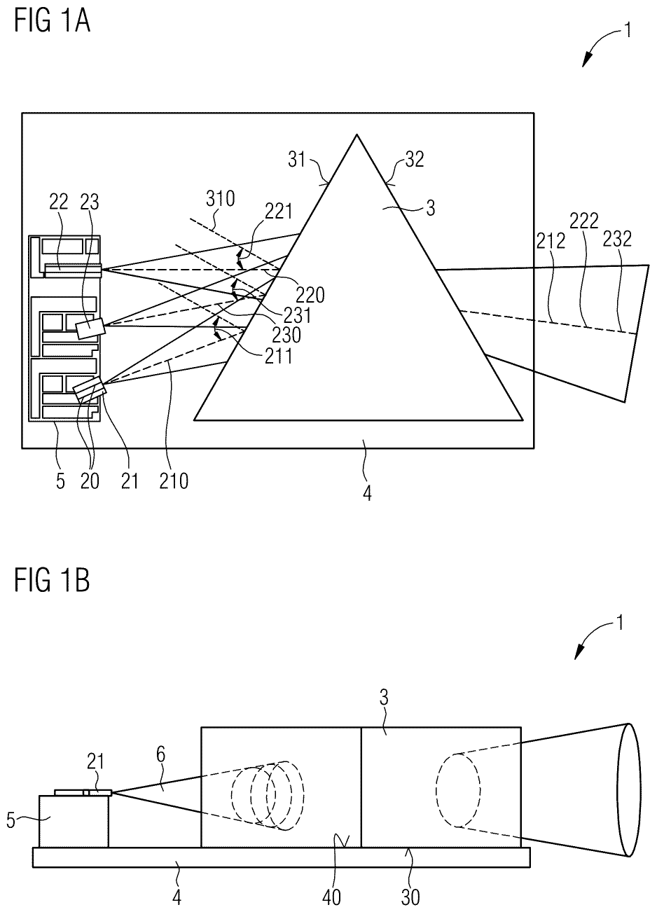

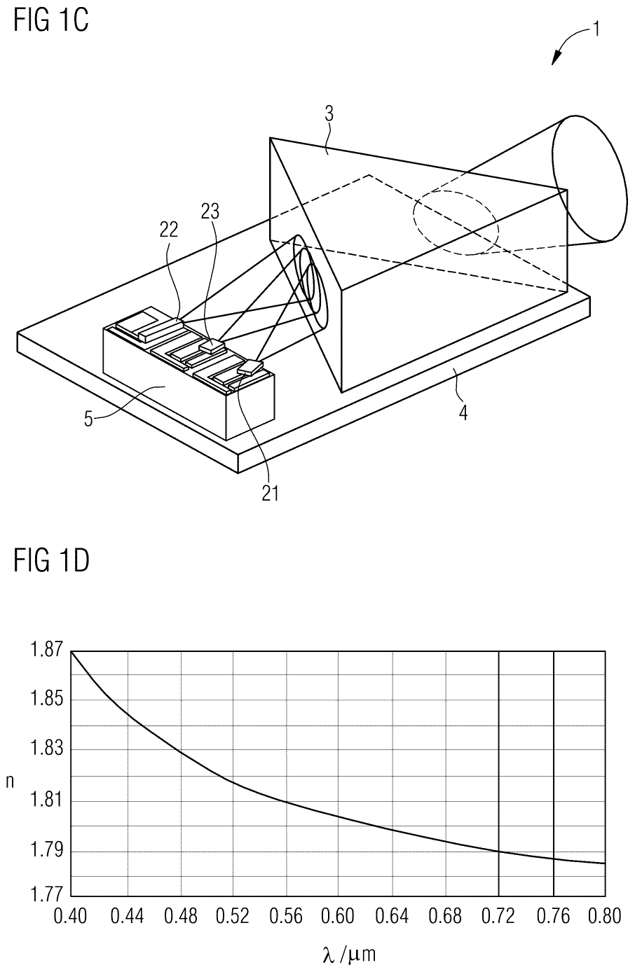

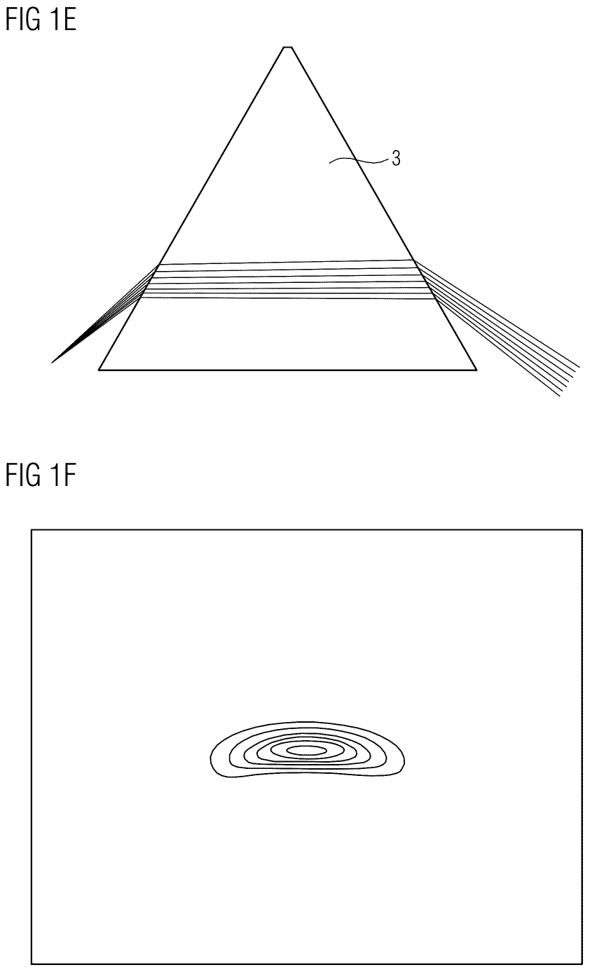

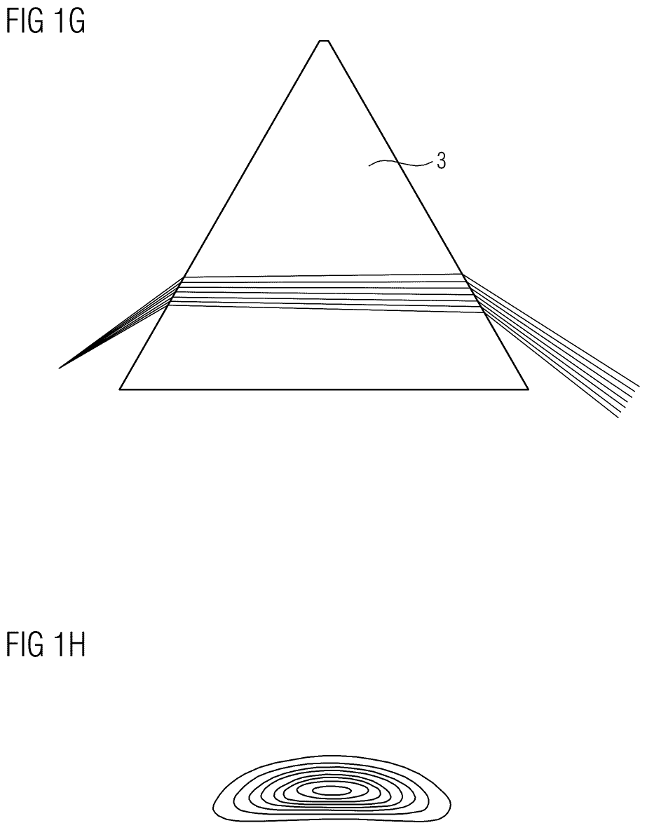

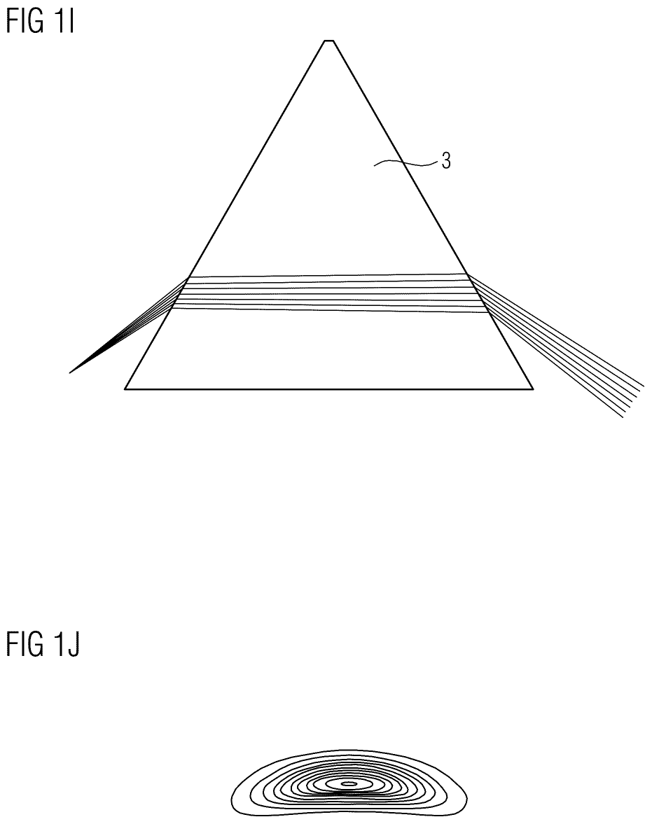

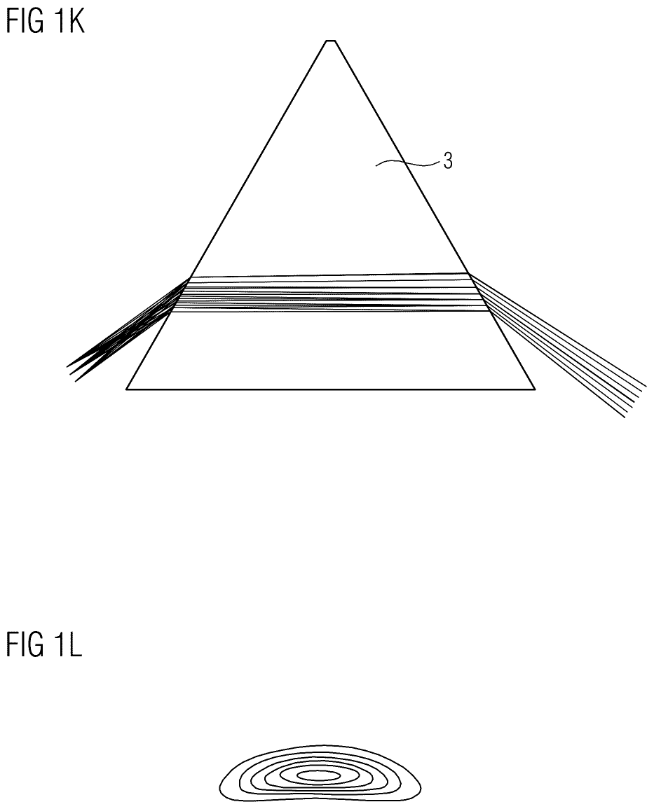

FIGS. 1A to 1C show an example of a semiconductor laser device 1, wherein the semiconductor laser device 1 comprises a first semiconductor laser 21, a second semiconductor laser 22, and a third semiconductor laser 23.

The first semiconductor laser 21 is configured to emit, during operation of the semiconductor laser device 1, a first radiation with a first wavelength of maximum intensity along a first main emission direction 210. The second semiconductor laser 22 is configured to emit, during operation of the semiconductor laser device, a second radiation with a second wavelength of maximum intensity that is greater than the first wavelength of maximum intensity along a second main emission direction 220. The third semiconductor laser 23 is configured to emit a third radiation with a third wavelength of maximum intensity along a third main emission direction 230 during operation of the semiconductor laser device 1. For example, the first semiconductor laser 21 is configured to emit radiation in the blue spectral range, the second semiconductor laser 22 is configured to emit radiation in the red spectral range, and the third semiconductor laser 23 is configured to emit radiation in the green spectral range, so that, in operation, the semiconductor laser device 1 can emit mixed light that appears white to the human eye.

However, the semiconductor laser device 1 may also comprise only two semiconductor lasers or more than three semiconductor lasers with different wavelengths of maximum intensity. Furthermore, two or more of the semiconductor lasers 21, 22, 23 may be provided for emitting radiation in the same spectral range, for example in the green spectral range. In this case, the wavelengths of maximum intensity between the semiconductor lasers are advantageously different from each other in pairs to such an extent that the semiconductor lasers can be placed next to each other at a sufficiently small distance from the prismatic element 3.

The semiconductor laser device 1 further comprises a prismatic element 3 with a base area 30, a radiation entry surface 31 and a radiation exit surface 32, wherein the radiation entry surface 31 and the radiation exit surface 32 are side surfaces of the prismatic element 3 which are oblique to each other and opposite to each other. The first radiation, the second radiation and the third radiation each impinge on the radiation entry surface of the prismatic element 3.

The first main emission direction 210, the second main emission direction 220 and the third main emission direction 230 are each arranged at different angles to a normal 310 of the radiation entry surface 31, so that the prismatic element causes these radiation components to overlap and the semiconductor laser device 1 emits the first radiation, the second radiation and the third radiation in an overlapping manner at the radiation exit surface 230. After exiting the radiation exit surface 32, a first main radiation direction 212 of the first semiconductor laser 21, a second main radiation direction 222 of the second semiconductor laser and a third main radiation direction 232 of the third semiconductor laser 23 are congruent. However, deviating from this ideal case, there may also be a small angle between these main radiation directions, for example an angle of at most 5°, or at most 3°, or at most 1°.

After exiting the respective semiconductor lasers 21, 22, 23, the radiation from the semiconductor lasers 21, 22, 23 passes through a free beam region 6 until the radiation impinges on the prismatic element 3. The prismatic element 3 is therefore the first element on which the radiation impinges after entering a gaseous medium. Collimation of the radiation from the semiconductor lasers 21, 22, 23 before it impinges on the prismatic element 3 is not necessary. However, an optical element may also be arranged between the semiconductor lasers 21, 22, 23 and the prismatic element 3 to collimate the radiation. Alternatively or in addition, an optical element for collimation may also be arranged directly on the facets of the semiconductor lasers 21, 22, 23.

In the embodiment shown, the base area 30 of the prismatic element 3 has a triangular shape. However, this is not mandatory. For example, the prismatic element 3 may be rounded or bevelled at one or more corners, as long as the area of the radiation entry surface 31, onto which the laser radiation impinges, and the area of the radiation exit surface 32, from which the superimposed radiation exits the prismatic element 3, are flat.

FIG. 1D shows an example of the refractive index profile for a prismatic element 3 made of SF6 flint glass. This material exhibits a comparatively large relative dispersion, so that the refractive index for radiation in the red spectral range and for radiation in the blue spectral range differ comparatively strongly from each other.

As shown in FIG. 1A, a first angle 211 between the first main emission direction 210 and a normal 310 of the radiation entry surface 31 is greater than a second angle 221 corresponding to a refractive index between the second main emission direction 220 and the normal 310 and greater than a third angle 231 between the third main emission direction 230 and the normal 310. In accordance with the law of refraction, the different radiation components are refracted to different degrees by the refractive index of the prismatic element 3, which is decisive for the respective wavelength, when they enter through the radiation entry surface 31 and subsequently impinge on the radiation exit surface 32 directly, where they are refracted again when they exit the prismatic element 3.

By using a material for the prismatic element 3 that has a comparatively high relative dispersion and correspondingly low Abbe number, the angles 211, 221, 231 for the respective main emission directions 210, 220, 230 relative to the normal 310 are relatively large, so that the semiconductor lasers 21, 22, 23 can be arranged at a relatively small distance from the prismatic element 3 in such a way that the prismatic element 3 superimposes the radiation components. In principle, however, a different material can also be used for the prismatic element 3, such as a flint glass with an Abbe number of at most 30 or a flint glass with an Abbe number in a range from 30 to 50 or a crown glass.

In the embodiment shown, the first semiconductor laser 21, the second semiconductor laser 22, and the third semiconductor laser 23 are attached to a mounting carrier 4 with a mounting surface 40 of the semiconductor laser device 1. The semiconductor lasers 21, 22, 23 can be arranged on a common intermediate carrier 5 or on separate intermediate carriers. The prismatic element 3 is fastened with its base area 30 to the mounting carrier 4 so that the base area 30 extends parallel to the mounting surface 4 of the mounting carrier 40.

The first main emission direction 210, the second main emission direction 220, and the third main emission direction 230 each extend parallel to the base area 30 of the prismatic element. The first semiconductor laser 21, the second semiconductor laser 22, and the third semiconductor laser 23 are each configured as edge-emitting semiconductor lasers, with an axis of fast divergence running perpendicular to the base area 30 of the prismatic element 3. In an edge-emitting semiconductor laser, the axis of fast divergence runs perpendicular to a main extension plane of the semiconductor layers of the semiconductor laser and thus typically perpendicular to a fastening area of the intermediate carrier 5 to which the semiconductor laser 1 is fastened.

The first semiconductor laser 21, the second semiconductor laser 22, and the third semiconductor laser 23 can optionally have multiple emission regions 20. This is shown in FIG. 1A as an example for the first semiconductor laser 21. In FIG. 1A, the emission regions 20 of the first semiconductor laser 21 are arranged next to each other in a plane parallel to the base area 30 of the prismatic element 3. This applies analogously to the second semiconductor laser 22 and the third semiconductor laser 23.

FIG. 1E illustrates a beam path for radiation from the first semiconductor laser 21 in the blue spectral range, with FIG. 1F showing a contour diagram of the emitted beam profile of the first semiconductor laser 21. FIGS. 1G and 1H show corresponding simulations for an emission of the second semiconductor laser 22 in the red spectral range. Accordingly, FIGS. 1I and 1J show corresponding simulations for the radiation of the third semiconductor laser 23 in the green spectral range.

FIGS. 1K and 1L illustrate the corresponding superposition of these three radiation components. The simulations prove that the prismatic element 3 can be used to achieve a highly efficient superposition of the radiation components of the first semiconductor laser 21, the second semiconductor laser 22, and the third semiconductor laser 23 to produce white light.

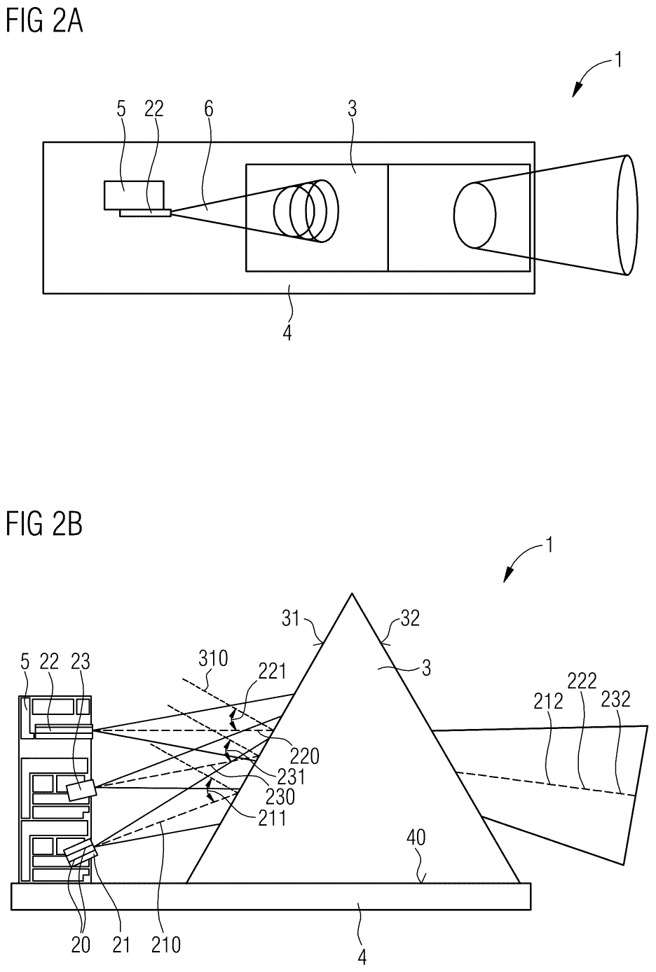

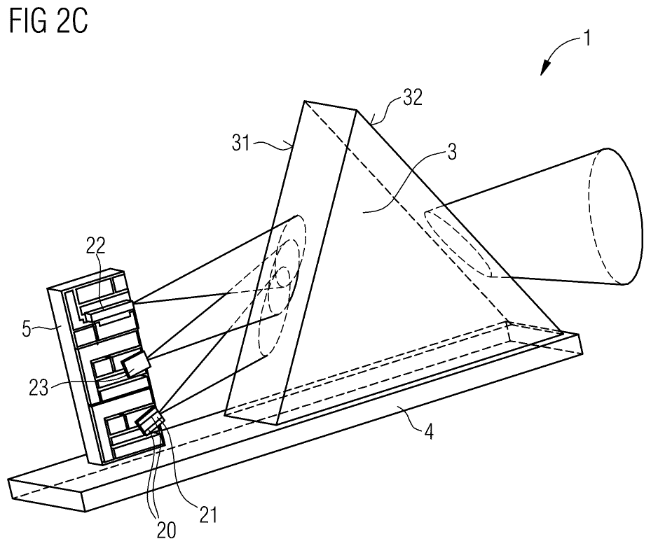

The exemplary embodiment shown in FIGS. 2A to 2C essentially corresponds to the exemplary embodiment described in connection with FIGS. 1A to 1L. In contrast to this, the base area 30 of the prismatic element extends perpendicular to the mounting surface 40 of the mounting carrier 4. Viewed along a vertical direction perpendicular to the mounting surface 40, the first semiconductor laser 21, the second semiconductor laser 22, and the third semiconductor laser 23 are arranged one above the other so that the first main emission direction 210, the second main emission direction 220 and the third main emission direction 230, when viewed in plan view of the semiconductor laser device 1, each extend parallel to the base area 30 of the prismatic element 3.

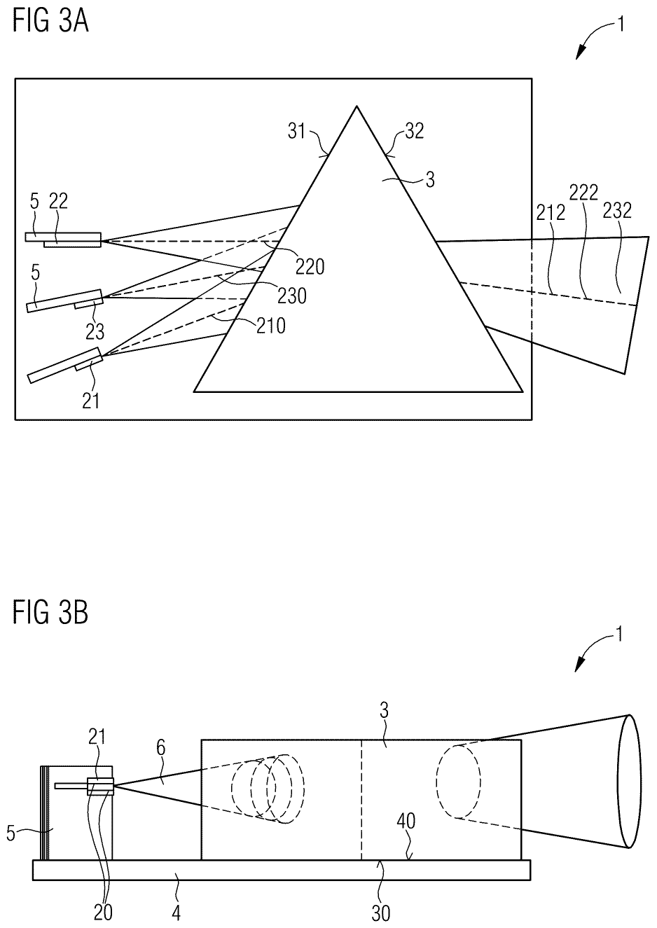

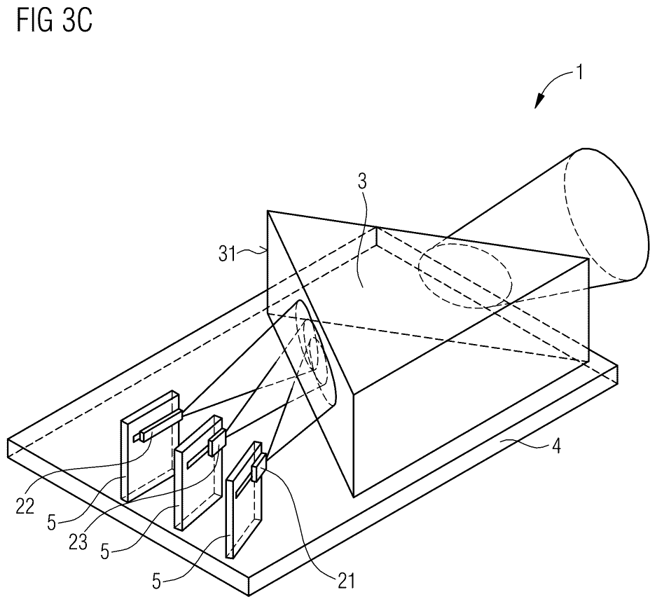

The embodiment shown in FIGS. 3A to 3C essentially corresponds to the embodiment described in connection with FIGS. 1A to 1L.

In contrast, the axes of fast divergence of the first semiconductor laser 21, the second semiconductor laser 22, and the third semiconductor laser 23 extend parallel to the base area 30 of the prismatic element 3.

The emission regions 20 of the semiconductor lasers 21, 22, 23 are arranged next to one another in a direction perpendicular to the base area 30. For each semiconductor laser 21, 22, 23, the regions areas 20 of the semiconductor laser thus overlap completely or at least partially in a top view of the base area 30 of the prismatic element 3.

The semiconductor lasers 21, 22, 23 are each arranged on a separate intermediate carrier 5. This simplifies the alignment of the individual semiconductor lasers 21, 22, 23 with respect to the prismatic element 3.

The semiconductor lasers 21, 22, 23 are each fastened to a fastening area of the intermediate carrier 5 which runs perpendicular to the base area 30 of the prismatic element 3. In the exemplary embodiment shown, the base area 30 of the prismatic element extends parallel to the mounting surface 40 of the mounting carrier 4. However, the base area 30 of the prismatic element 3 can also extend perpendicular to the mounting surface 40, as described in connection with FIGS. 2A to 2C. In this case, the alignment of the fast divergence axes parallel to the base area 30 of the prismatic element 3 can be maintained by rotating the semiconductor lasers by 90° relative to the mounting surface 40.

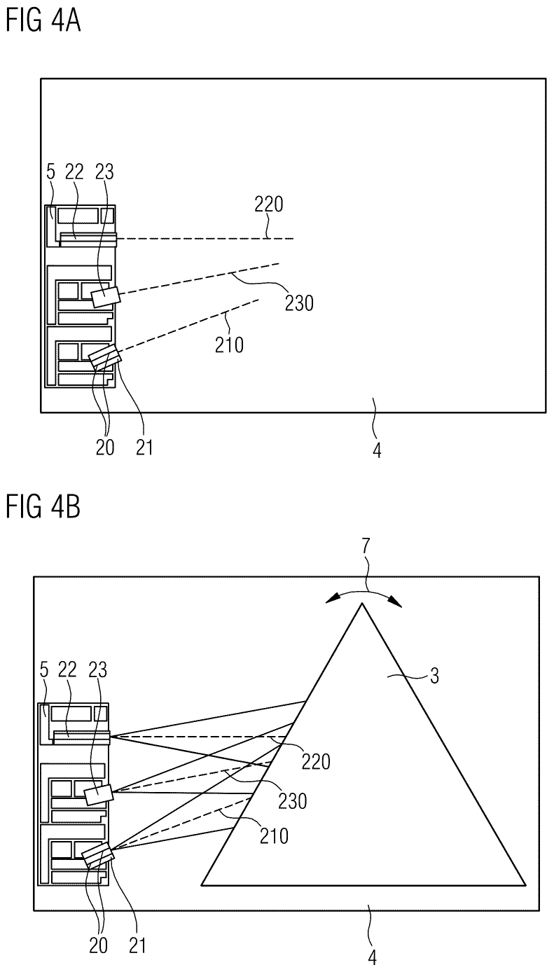

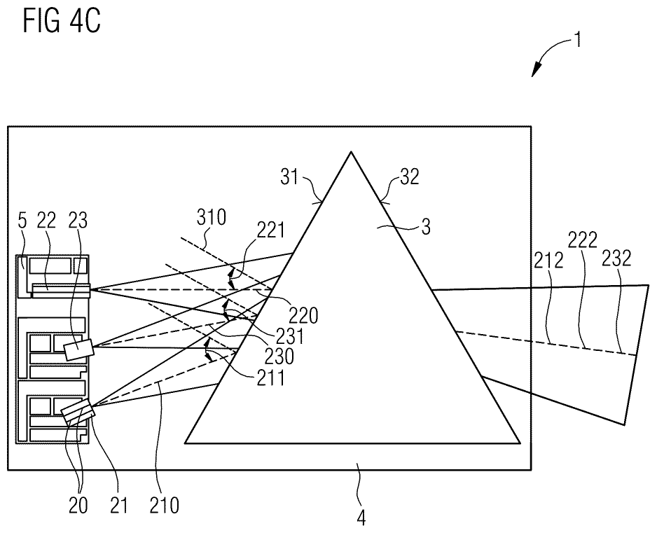

FIGS. 4A to 4C show an exemplary embodiment of a method for manufacturing a semiconductor laser device 1 using intermediate steps shown in plan view, wherein a semiconductor laser device 1 is manufactured as an example, which is configured as described in connection with FIG. 1A. However, the method is also suitable for other configurations of the semiconductor laser device 1.

As shown in FIG. 4A, the first semiconductor laser 21, the second semiconductor laser 22, and the third semiconductor laser 23 are attached to a mounting surface 40 of the mounting carrier 4. This is done without active adjustment by passively placing the semiconductor lasers 21, 22, 23 at predefined positions and with predefined angles of the main radiation axes 210, 220, 230 relative to each other.

Next, as shown in FIG. 4B, the prismatic element 3 is arranged on the mounting carrier 4. Before being fixed to the mounting carrier 4, the prismatic element 3 can be rotated about its axis extending perpendicular to the base area 30 in order to optimize the superposition of the radiation components of the first semiconductor laser 21, the second semiconductor laser 22, and the third semiconductor laser 23. This is illustrated by an arrow 71.

This method is particularly cost-effective. Furthermore, at the time of mounting the semiconductor lasers 21, 22, 23, the prismatic element 3 is not yet fixed to the mounting carrier 4, so that methods which are carried out at comparatively high temperatures, for example soldering or sintering, can also be used to fix the semiconductor lasers 21, 22, 23.

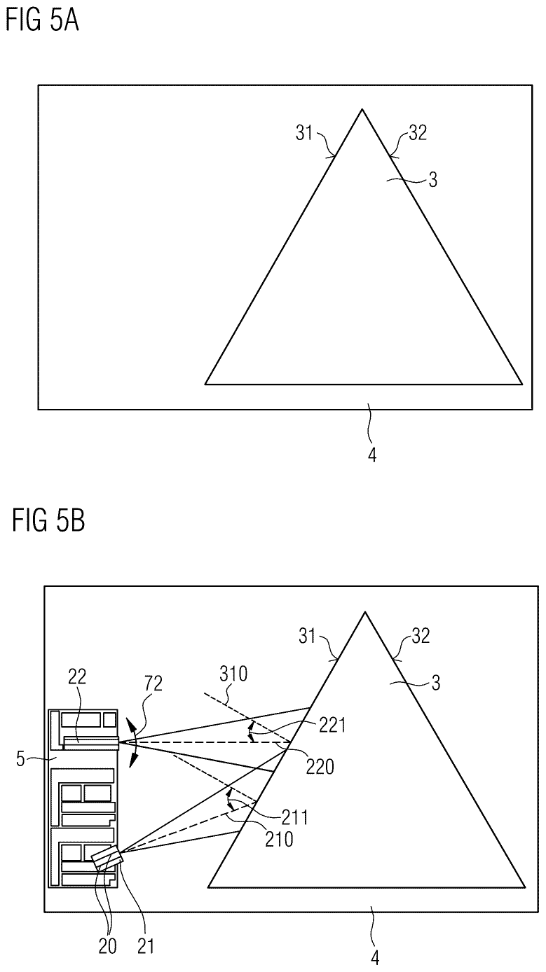

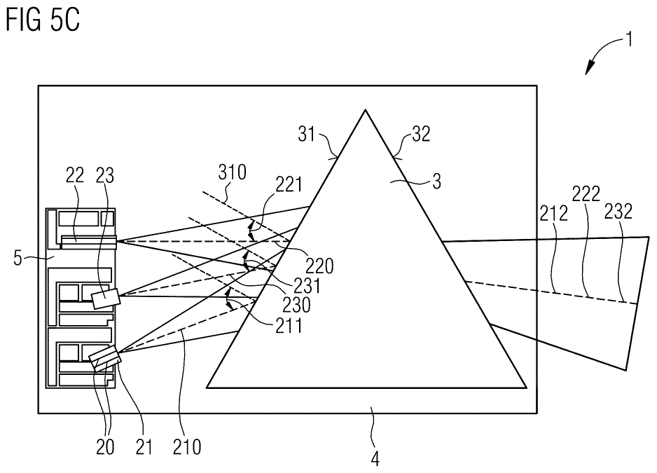

In the embodiment of a method shown in FIGS. 5A to 5C, in contrast to the previous exemplary embodiment, the prismatic element 3 is fixed to the mounting carrier 4 in a first step (FIG. 5A).

The semiconductor lasers are then mounted. In the stage shown in FIG. 5B, the first semiconductor laser 21 is already mounted and the second semiconductor laser 22 is positioned, as illustrated by an arrow 72, with respect to its second main emission direction 220 so that the radiation components are optimally superimposed by the prismatic element 3.

The third semiconductor laser 23 or, if necessary, further semiconductor lasers can be handled in the same way, so that overall a particularly precise superposition of the individual radiation components can be achieved.

In this case, the semiconductor lasers 21, 22, 23 are preferably mounted using a method that does not require high temperatures in order to avoid damage to the prismatic element 3 or to a connection between the prismatic element 3 and the mounting carrier 4. For example, an adhesive bond, activated by ultraviolet radiation, is suitable.

The invention is not limited by the description based on the exemplary embodiments. Rather, the invention encompasses every new feature and every combination of features, including in particular every combination of features in the patent claims, even if this feature or combination itself is not explicitly stated in the patent claims or the exemplary embodiments.

1. A semiconductor laser device comprising:
a first semiconductor laser which is configured to emit, during operation of the semiconductor laser device a first radiation with a first wavelength of maximum intensity along a first main emission direction;
a second semiconductor laser which is configured to emit, during operation of the semiconductor laser device, a second radiation with a second wavelength of maximum intensity which is greater than the first wavelength of maximum intensity, along a second main emission direction; and
a prismatic element with a base area, a radiation entry surface and a radiation exit surface,
wherein
the radiation entry surface and the radiation exit surface are side surfaces of the prismatic element which are oblique to each other and opposite to each other;
the first radiation and the second radiation impinge on the radiation entry surface of the prismatic element;
the first main emission direction and the second main emission direction are arranged relative to a normal of the radiation entry surface such that the semiconductor laser device emits the first radiation and the second radiation superimposed at the radiation exit surface; and
at least one of the semiconductor lasers comprises a plurality of emission regions.

2. The semiconductor laser device according to claim 1,
wherein the prismatic element has a higher refractive index for the first wavelength of maximum intensity than for the second wavelength of maximum intensity, and
wherein the first main emission direction is arranged at a larger angle to the normal of the radiation entry surface than the second main emission direction.

3. The semiconductor laser device according to claim 1,
wherein a material of the prismatic element has an Abbe number of at most 50.

4. The semiconductor laser device according to claim 1,
wherein a material of the prismatic element has an Abbe number of at most 30.

5. The semiconductor laser device according to any of the previous claims,
wherein the first main emission direction and the second main emission direction extends parallel to the base area of the prismatic element.

6. The semiconductor laser device according to claim 1,
wherein the emission regions are arranged next to each other along a direction perpendicular to the base area of the prismatic element.

7. The semiconductor laser device according to claim 1,
wherein the emission regions are arranged next to one another along a direction extending parallel to the base area of the prismatic element.

8. The semiconductor laser device according to claim 1,
wherein the semiconductor laser device comprises a mounting carrier with a mounting surface, wherein the first semiconductor laser, the second semiconductor laser and the prismatic element are arranged on the mounting surface.

9. The semiconductor laser device according to claim 8,
wherein the base area of the prismatic element extends parallel to the mounting surface.

10. The semiconductor laser device according to claim 8,
wherein the base area of the prismatic element extends perpendicular to the mounting surface.

11. The semiconductor laser device according to claim 1,
wherein the first radiation and the second radiation pass through a free beam region after emerging from the first semiconductor laser and from the second semiconductor laser, respectively, and wherein the prismatic element immediately follows the free beam region.

12. The semiconductor laser device according to claim 1,
wherein the semiconductor laser device has a third semiconductor laser which is configured to emit, during operation of the semiconductor laser device, a third radiation with a third wavelength of maximum intensity along a third main emission direction, wherein the wavelengths of maximum intensity differ from each other in pairs by at least 50 nm.

13. A method of manufacturing a semiconductor laser device according to claim 1, comprising:
a) applying a prismatic element to a mounting carrier;
b) placing a first semiconductor laser on the mounting carrier; and
c) applying a second semiconductor laser to the mounting carrier.

14. The method according to claim 13,
wherein step a) is performed after at least one or both of steps b) and c).

15. The method according to claim 13,
wherein at least one or both of steps b) and c) are performed after step a).

16. A semiconductor laser device comprising:
a first semiconductor laser which is configured to emit, during operation of the semiconductor laser device, a first radiation with a first wavelength of maximum intensity along a first main emission direction;
a second semiconductor laser which is configured to emit, during operation of the semiconductor laser device, a second radiation with a second wavelength of maximum intensity which is greater than the first wavelength of maximum intensity, along a second main emission direction; and
a prismatic element with a base area, a radiation entry surface and a radiation exit surface,
wherein
the radiation entry surface and the radiation exit surface are side surfaces of the prismatic element which are oblique to each other and opposite to each other;
the first radiation and the second radiation impinge on the radiation entry surface of the prismatic element;
the first main emission direction and the second main emission direction are arranged relative to a normal of the radiation entry surface such that the semiconductor laser device emits the first radiation and the second radiation superimposed at the radiation exit surface;
at least one of the semiconductor lasers comprises a plurality of emission regions; and
both the first radiation and the second radiation undergo a refraction at the radiation entry surface and a refraction at the radiation exit surface when the radiation passes through the prismatic element.
